(19) United States
(12) Patent Application Publication
(10) Pub. No.: US 2008/0213559 A1
(43) Pub. Date: Sep. 4, 2008

(54) PHOSPHOR FILM AND METHOD OF PRODUCING THE PHOSPHOR FILM

(75) Inventors: Tomoyuki Oike, Yokohama-shi (JP); Tatsuya Iwasaki, Machida-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/034,339

(22) Filed: Feb. 20, 2008

(30) Foreign Application Priority Data
Mar. 2, 2007 (JP) 2007-052849

(51) Int. Cl. B32B 9/00; B05D 3/02; C23C 14/06

(52) U.S. Cl. 428/220; 427/350; 427/248.1; 427/597; 204/192.1

(57) ABSTRACT

A phosphor film high in efficiency and less in luminescence irregularity and a method of producing the phosphor film are provided. The phosphor film includes a zinc sulfide compound containing an additive element(s). The additive element is at least one element selected from the group consisting of Ag, Cu and Au; the concentration of the additive element is 0.2 mol % or more and 5 mol % or less with respect to Zn; and the film thickness of the phosphor film is 10 nm or more and 2 um or less.

### BACKGROUND OF THE INVENTION

1. Field of the Invention

The present invention relates to a phosphor film and a method of producing the phosphor film.

2. Description of the Related Art

A phosphor using a zinc sulfide compound has been studied for many years, and has been put into practical use. For example, a powdery zinc sulfide phosphor synthesized by a solid reaction method contains an activator and a co-activator, and causes donor-acceptor pair luminescence. The powdery zinc sulfide phosphor is used for, for example, a cold cathode display tube, a cathode-ray tube (CRT), or a dispersed inorganic EL element. As a luminescent material, for example, ZnS:Ag, Cl, ZnS:Cu, Al, or ZnS:Cu, Au, Al is used.

A thin-film zinc sulfide compound phosphor produced by a vacuum film formation method contains an element as a luminescence center and emits light by collision excitation. This phosphor has a double insulation structure in which a dielectric film is superimposed on, for example, a glass substrate, a ceramic substrate, or a thick-film dielectric substrate, and is used for an inorganic EL display panel. As the luminescent material, for example, ZnS:Mn is used.

Referring to a conventional technology, there is a method which involves several calcination processes so as to increase the luminance of a powdery zinc sulfide phosphor. For the purpose of preparing particles having a certain uniform diameter, a flux addition method or a particle size-controlling agent addition method is employed in some cases. There is a method in which mechanical impact is applied to generate many defects in zinc sulfide crystals. A hydrothermal synthesis method has also been used in place of a solid reaction method.

Most of conventional powdery zinc sulfide phosphors utilize the fact that donor-acceptor pair luminescence is brought about when a slight amount of activator and co-activator are added thereto. In this case, the concentration of the activator ranges from about 0.01 mol % to about 0.15 mol % with respect to Zn (Japanese Patent Application Laid-open No. H08-087965) and it is known that when the concentration of the activator increases, luminescence becomes very weak due to concentration quenching.

Therefore, the luminance attained in such phosphors using the zinc sulfide compound as a luminescent material is insufficient.

### SUMMARY OF THE INVENTION

The present invention aims to provide a phosphor film which is highly efficient and has little unevenness in luminescence, and a method of producing the phosphor film.

A phosphor film according to the present invention includes a zinc sulfide compound containing an additive element therein, wherein the additive element is at least one element selected from the group consisting of Ag, Cu and Au, a concentration of the additive element is 0.2 mol % or more and 5 mol % or less with respect to Zn, and a film thickness of the phosphor film is 10 nm or more and 2 um or less.

A method of producing a phosphor film according to the present invention includes: forming a sulfide film on a substrate using a zinc sulfide compound and an additive element as material supplying sources; and heating the sulfide film at 600° C. or higher in vacuum or in an inert gas.

The present invention can provide a phosphor film which is highly efficient and less in luminescence irregularity, and a method of producing the phosphor film.

Further features of the present invention will become apparent from the following description of exemplary embodiments with reference to the attached drawings.

### BRIEF DESCRIPTION OF THE DRAWINGS

FIG. 1 is a schematic diagram illustrating an example of a vacuum deposition device which can be used for a method of producing a phosphor film according to the present invention.

FIG. 2 is a diagram illustrating a correlation between a heat treatment temperature and a heat treatment time, and luminescent brightness of a phosphor film produced by the present invention.

### DESCRIPTION OF THE EMBODIMENTS

Hereinafter, the present invention will be described with reference to the accompanying drawings.

A phosphor film of the present invention includes a zinc sulfide compound which contains an additive element therein. According to the present invention, there is no limitation on the zinc sulfide compound insofar as the compound contains zinc sulfide as a matrix. For example, a compound having a certain crystal structure such as a zinc blende structure (cubic system), a wurtzite structure (hexagonal system), a laminated structure thereof, or a combined structure thereof may be used.

In the phosphor film of the present invention, as an additive element to be added to the zinc sulfide compound, any element can be used inasmuch as the element causes donor-acceptor pair luminescence with a zinc sulfide compound. In particular, at least one element selected from the group consisting of Ag, Cu and Au may be used as the additive element. In the phosphor film of the present invention, the additive element may be of a single type or two or more types. In the phosphor film of the present invention, the concentration of the additive element is 0.2 mol % or more and 5 mol % or less in total with respect to an amount of zinc (Zn).

In the phosphor film of the present invention, when Ag, for example, is used as the additive element, the concentration of Ag to be added to the zinc sulfide compound is 0.2 mol % or more and 5 mol % or less with respect to Zn. The concentration of Ag may be 0.3 mol % or more and 3 mol % or less, and more particularly, may be 1 mol % or more and 3 mol % or less. When the concentration of Ag falls within the above range, efficient luminescence can be achieved. In the phosphor film of the present invention, when Cu, for example, is used as the additive element, the concentration of Cu to be added to the zinc sulfide compound is 0.2 mol % or more and 5 mol % or less with respect to Zn. The concentration of Cu to be added to the zinc sulfide compound may be 1 mol % or more and 5 mol % or less, and more particularly, may be 4 mol % or more and 5 mol % or less. When the concentration of Cu falls within the above range, efficient luminescence can be achieved.

The phosphor film of the present invention may contain various metallic elements together with the above-mentioned additive element. Examples of the metallic elements include Au, alloys of those metallic elements, and mixtures of those metallic elements, in addition to the additive elements. The phosphor film of the present invention may contain various elements in addition to the above-mentioned elements, as a means for forming a donor level in a compound of the phosphor film. Examples of the various elements include F, Cl, Br, or I, and B, Al, Ga, or In. In particular, the content of F, Cl, Br, or I in the phosphor film of the present invention may be less than 0.1 mol % with respect to Zn. Moreover, the content of B, Al, Ga, or In in the phosphor film of the present invention may be less than 0.1 mol % with respect to Zn. Further, the content of F, Cl, Br or I, and B, Al, Ga, or In in the phosphor film of the present invention may be less than 0.1 mol % with respect to Zn.

There is no limitation on a method of identifying a material composition of the phosphor film of the present invention, and the method includes, for example, fluorescent-X-ray measurement, energy dispersion spectrometry, or high-frequency induction coupling plasma emission spectrometry.

In the phosphor film of the present invention, the film thickness of the phosphor film is 10 nm or more and 2 μm or less, and may be 40 nm or more and 1 μm or less. When the film thickness is too small, luminescence becomes weak. When the film thickness is too large, luminescent brightness is saturated and the internal stress of the film increases, whereby the adhesion strength of the film to the substrate becomes insufficient. In particular, when the film thickness falls within the range from 40 nm to 1 μm, the continuity of the film is maintained and the luminescence irregularity can be reduced, and therefore the film is hard to peel off the substrate. The film thickness may be measured by various known methods in the art. For example, the following may be cited: fluorescent-X-ray measurement, stylus film-thickness level difference measurement, and scanning electron microscope observation.

The excitation spectrum of the phosphor film in which Ag is contained as the additive element in the zinc sulfide compound has a peak at 334 nm. When the emission spectrum excited by ultraviolet light of 334 nm is measured, a center wavelength is 448 nm and a half value width is 53 nm. The excitation spectrum of the phosphor film in which Cu is contained as the additive element in the zinc sulfide compound has a peak at 336 nm. When the emission spectrum excited by ultraviolet light of 336 nm is measured, a center wavelength is 519 nm and a half value width is 69 nm.

Because the waveforms of these emission spectra are substantially in agreement with the emission spectra of zinc sulfide phosphor particles for a common CRT, donor-acceptor pair luminescence is considered to be brought about. However, the additive element of the phosphor film using the zinc sulfide compound of the present invention is only an additive element which can serve as an acceptor, and an addition concentration of the additive element is also as high as several percent with respect to Zn. It is considered that, by adding the additive element capable of serving as an acceptor to a zinc sulfide compound at a high concentration, holes of sulfur atoms are formed and a donor is formed in the phosphor film.

In the phosphor film of the present invention, there is no limitation on a crystalline state of particles forming a phosphor film insofar as the donor-acceptor pair luminescence is not affected. In particular, an example of the crystalline structure of the phosphor film include a zinc blende structure having no symmetry center.

The crystalline state of particles may be analyzed by X-ray diffraction measurement and the use of a CuKα ray enable a zinc blende structure to be determined.

(Method of Producing a Phosphor Film According to the Present Invention)

The method of producing a phosphor film according to the present invention involves forming a sulfide film on a substrate using a zinc sulfide compound and an additive element as material supplying sources, and heating the sulfide film at 600° C. or more in vacuum or in an inert gas.

In the method of producing a phosphor film according to the present invention, a sulfide film may be formed using various film formation methods. Examples of the method include a vacuum deposition method, a solution growth method, an organic metal chemical vapor transportation method, a vapor growth method, a sputtering method, and a laser abrasion method. Of these, a multiple vacuum deposition method may be used because the concentration of the additive element can be controlled more easily. In the formation of the sulfide film, examples of materials used as material supplying sources include zinc sulfide compounds containing the additive element and the above-mentioned metallic elements, in addition to the above-mentioned zinc sulfide compounds and additive elements. It should be noted that the additive element can be added by ion implantation before or after the formation of a matrix material including zinc sulfide.

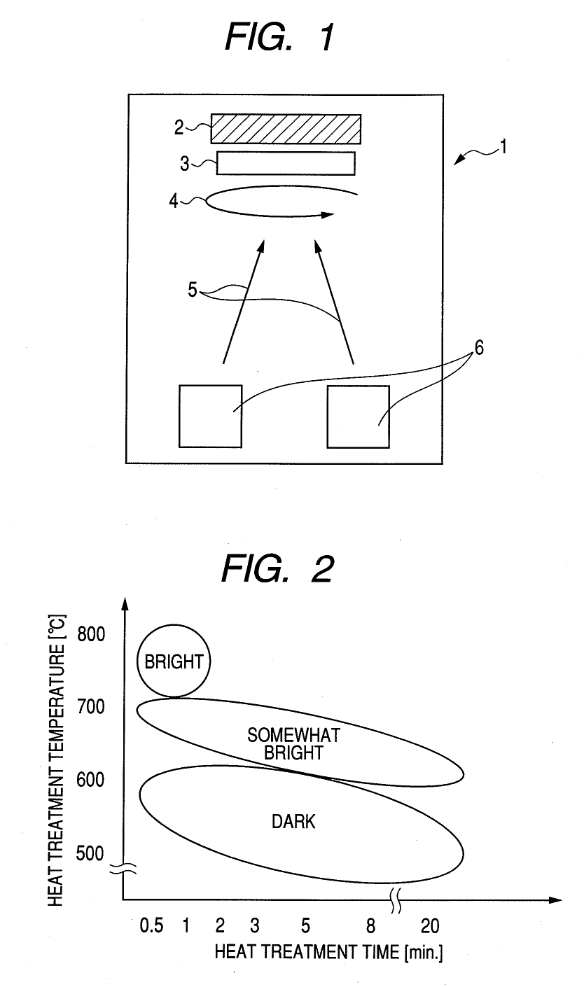

FIG. 1 is a schematic diagram illustrating an example of a vacuum evaporation device which can be used for the method of producing a phosphor film according to the present invention. The vacuum evaporation device has a vacuum chamber 1, a substrate 3 to which the above-mentioned zinc sulfide compound and additive element are supplied, a substrate heater 2 for heating the substrate 3, a unit 4 for rotating the substrate 3, and a material supplying source 6 including those compounds and elements.

By using the vacuum evaporation device having multiple material supplying sources as shown in FIG. 1, the zinc sulfide compound and the additive element can be separately supplied to the substrate, to thereby produce a phosphor film containing the additive element in a desired addition concentration.

In the formation of a sulfide film, a temperature of a substrate to which the material is supplied, may be 100° C. or more and 300° C. or less, and more particularly, may be 150° C. or more and 250° C. or less. When the substrate temperature is excessively high, the zinc sulfide compound which has once adhered to the substrate is re-evaporated, and the film is difficult to form. When the substrate temperature is excessively low, impurities such as moisture and oil are mixed in the phosphor film, and the crystallinity of the phosphor film is lowered.

The concentration of the additive element in the phosphor film of the present invention is as low as several mol % with respect to Zn. Therefore, when a rate of supplying the zinc sulfide compound to the substrate is low, the additive element supplying rate becomes very low and is difficult to control. Accordingly, it is preferable that the rate of supplying the zinc sulfide compound is set to be in a controllable range to perform film formation. However, when the rate of supplying the zinc sulfide compound is too high, it is difficult to control film thickness. In view of the above, the rate of supplying the zinc sulfide compound may be 100 nm/minute or more and 1,500 nm/minute or less, and more preferably 300 nm/minute or more and 700 nm/minute or less so as to obtain a more efficient phosphor film. In particular, when the rate of supplying the zinc sulfide compound is lower than 300 nm/minute, in order to bring an error of the supplying rate of the additive element into, for example, 10% or less, the supplying rate comes to be controlled with an accuracy of at least 1.5 nm/minute or less, and more particularly with an accuracy of 0.9 nm/minute or less. In this case, it becomes difficult to stably supply the additive element. When the rate of supplying the zinc sulfide compound exceeds 700 nm/minute, in order to bring an error of the film thickness into, for example, 10% or less, the film formation time is controlled with an accuracy of 20 seconds or less, and more particularly with an accuracy of 5 seconds or less. In this case, it becomes difficult to control the film thickness.

In the method of producing the phosphor film of the present invention, there is no limitation on heat treatment of a sulfide film insofar as an atmosphere of vacuum or an inert gas can be controlled. For example, a common electric furnace may be used and a rapid heating method capable of controlling a heating/cooling time may be used. A heating unit, a lamp and a laser may be used in addition to a heater. A heat treatment temperature may be 600° C. or more as illustrated in FIG. 2. When the heat treatment temperature falls within the above-mentioned range, crystallization of the zinc sulfide compound progresses and the additive element can be dispersed into the phosphor film. Further, in order to obtain a more efficient phosphor film, it is more preferable that the heat treatment temperature is set to be 700° C. or more.

### EXAMPLES

Hereinafter, the present invention will further be described by way of Examples, but is by no means limited thereto.

### Example 1

This example is a first example of producing a phosphor film which contains Ag as an additive element in a zinc sulfide compound in a concentration of 0.2 mol % or more and 5 mol % or less with respect to Zn and has a film thickness of 10 nm or more and 2 μm or less.

A sulfide film having a film thicknesses of 400 nm is formed on an Si substrate using a zinc sulfide compound and Ag as an additive element with a multiple vacuum evaporation device. The film formation conditions of the sulfide film are as follows.
Substrate temperature: 150° C.
Material supplying rate: 500 nm/minute (zinc sulfide compound), 15 nm/minute (Ag)

When the formed sulfide film is subjected to high-frequency induction coupling plasma emission spectrometry, the concentration of Ag is 1.6 mol % with respect to Zn. In this sulfide film, the contents of B, Al, Ga or In, and F, Cl, Br, or I are each less than 0.1 mol % with respect to Zn.

After that, heat treatment is performed at 750° C. for one minute in an vacuum atmosphere of about 1×10⁻² Pa with an infrared lamp annealing apparatus and using a vacuum pumping system in which an oil sealed rotary pump and a turbine pump are combined, thereby obtaining a phosphor film. When the phosphor film thus obtained is irradiated with excitation light having a wavelength of 312 nm using a UV lamp, uniform bright blue light having a center wavelength of 448 nm and a half value width of 53 nm can be obtained. When the concentration of Ag is 0.29 mol % or 3.1 mol %, somewhat bright uniform blue light can be obtained by the same ultraviolet radiation excitation (see Table 1).

TABLE 1

| Ag concentration | |
|---|---|
| (mol %) | Luminescent brightness |
| 0.1 | Very dark |
| 0.3 | Somewhat bright |
| 2 | Bright |
| 3 | Somewhat bright |
| 5 | Dark |
| 8 | Very dark |

Moreover, when the phosphor film obtained by heating is subjected to X-ray diffraction measurement using CuKα rays, main diffraction peaks are observed at 2 theta=28.6°, 47.6°, and 56.5°, and it is seen that many zinc blende structures are formed.

According to this Example, by producing a zinc sulfide compound film containing Ag in a concentration of 0.3 mol % or more and 3 mol % or less according to the method of producing the phosphor film of the present invention, a phosphor film high in efficiency and less in luminescence irregularity can be obtained with enhanced reproducibility.

### Example 2

This example is a second example of producing a phosphor film which contains Cu as an additive element in a zinc sulfide compound in a concentration of 0.2 mol % or more and 5 mol % or less with respect to Zn and has a film thickness of 10 nm or more and 2 μm or less.

A sulfide film having a film thickness of 800 nm is formed on a quartz substrate using a zinc sulfide compound and Cu as an additive element with a multiple vacuum evaporation device. The film formation conditions of the sulfide film are as follows.
Substrate temperature: 250° C.
Material supplying rate: 600 nm/minute (zinc sulfide compound), 20 nm/minute (Cu)

When the formed sulfide film is subjected to high-frequency induction coupling plasma emission spectrometry, the concentration of Cu is 4.4 mol % with respect to Zn. In this sulfide film, the contents of B, Al, Ga or In, and F, Cl, Br, or I are less than 0.1 mol % with respect to Zn.

After that, heat treatment is performed at 650° C. for 20 minutes in a quartz tube annealing furnace which was made vacuum (about 1×10⁻³ Pa) using a vacuum pumping system in which an oil sealed rotary pump and a turbine pump are combined while supplying argon gas at 50 sccm, thereby obtaining a phosphor film. When the phosphor film thus obtained is irradiated with excitation light having a wave length of 312 nm using a UV lamp, as shown in Table 1, uniform bright green light having a center wavelength of 519 nm and a half value width of 69 nm can be obtained.

When the concentration of Cu is 0.96 mol % or 5.2 mol %, somewhat bright uniform green light can be obtained by the same ultraviolet radiation excitation (see Table 2).

TABLE 2

| Cu concentration | Luminescent |
|---|---|
| (mol %) | brightness |
| 0.1 | Very dark |
| 0.3 | Dark |
| 1 | Somewhat bright |
| 4 | Bright |
| 5 | Dark |
| 8 | Very dark |

Moreover, when the phosphor film obtained by heating is subjected to X-ray diffraction measurement using CuKα rays, main diffraction peaks are observed at 2 theta=28.6°, 47.6°, and 56.5°, and it is seen that many zinc blende structures are formed.

According to this Example, by producing a zinc sulfide compound film containing Cu in a concentration of 1 mol % or more and 5 mol % or less according to the method of producing the phosphor film of the present invention, a phosphor film high in efficiency and less in luminescence irregularity can be obtained with enhanced reproducibility.

### Example 3

This example is a third example of producing a phosphor film which contains Cu and Au as additive elements in a zinc sulfide compound in a concentration of 0.2 mol % or more and 5 mol % or less with respect to Zn and which has a film thickness of 10 nm or more and 2 μm or less.

A sulfide film having a film thickness of 500 μm is formed on an Si substrate with a thermal oxidation film using a zinc sulfide compound and an alloy of Au and Cu as additive elements by means of a multiple vacuum evaporation device. The film formation conditions of the sulfide film are as follows.
Substrate temperature: 250° C.
Material supplying rate: 600 nm/minute (zinc sulfide compound), 15 nm/minute (Alloy of Au and Cu)

When the formed sulfide film is subjected to high-frequency induction coupling plasma emission spectrometry, the concentration of Au is 1.9 mol % with respect to Zn and the concentration of Cu is 3.2 mol % with respect to Zn. In this sulfide film, the contents of B, Al, Ga, or In, and F, Cl, Br, or I are each less than 0.1 mol % with respect to Zn.

After that, heat treatment is performed at 700° C. for 2 minutes in an infrared lamp annealing apparatus which was made vacuum (about 10⁻² Pa) using a vacuum pumping system in which an oil sealed rotary pump and a turbine pump are combined while supplying nitrogen gas at 30 sccm. When the obtained phosphor film is irradiated with excitation light having a wavelength of 312 nm using a UV lamp, as shown in Table 2, uniform bright yellowish green light having a center wavelength of 550 nm and a half value width of 90 nm can be obtained.

Moreover, when the phosphor film obtained by heating is subjected to X-ray diffraction measurement using CuKα rays, main diffraction peaks are observed at 2 theta=28.6°, 47.6°, and 56.5°, and it is seen that many zinc blende structures are formed.

According to this Example, by producing a zinc sulfide compound film containing two additive elements, Au and Cu, according to the method of producing the phosphor film of the present invention, a phosphor film high in efficiency and less in luminescence irregularity can be obtained with enhanced reproducibility.

The phosphor film of the present invention can be used for image display devices such as a cold cathode display tube, a cathode-ray tube (CRT), and a dispersed inorganic EL element.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-052849, filed Mar. 2, 2007, which is hereby incorporated by reference in its entirety.

What is claimed is:

1. A phosphor film comprising a zinc sulfide compound which contains an additive element, wherein
the additive element is at least one element selected from the group consisting of Ag, Cu and Au,
a concentration of the additive element is 0.2 mol % or more and 5 mol % or less with respect to Zn, and
a film thickness of the phosphor film is 10 nm or more and 2 ρm or less.

2. A phosphor film according to claim 1, wherein the concentration of Ag is 0.3 mol % or more and 3 mol % or less with respect to Zn.

3. A phosphor film according to claim 1, wherein the concentration of Cu is 1 mol % or more and 5 mol % or less with respect to Zn.

4. A phosphor film according to claim 1, wherein a content of F, Cl, Br, or I in the zinc sulfide compound is less than 0.1 mol % with respect to Zn.

5. A phosphor film according to claim 1, wherein a content of B, Al, Ga, or In in the zinc sulfide compound is less than 0.1 mol % with respect to Zn.

6. A phosphor film according to claim 1, which has a zinc blende structure.

7. A method of producing a phosphor film, comprising:
forming a sulfide film on a substrate using a zinc sulfide compound and an additive element as material supplying sources; and
heating the sulfide film at 600° C. or higher in vacuum or in an inert gas.

8. A method of producing a phosphor film according to claim 7, wherein the material supplying source is selected from the group consisting of a zinc sulfide compound, a zinc sulfide compound containing an additive element and a metallic element.

9. A method of producing a phosphor film according to claim 7, wherein, in forming the sulfide film,
a temperature of the substrate is 100° C. or more and 300° C. or less, and
a material supplying rate of at least one of the material supplying sources is 100 nm/minute or more and 1,500 nm/minute or less.

10. A method of producing a phosphor film according to claim 9, wherein the material supplying rate of at least one of the material supplying sources is 300 nm/minute or more and 700 nm/minute or less.

11. A method of producing a phosphor film according to claim 7, wherein the sulfide film is formed by a method selected from the group consisting of a vacuum deposition method, a solution growth method, an organic metal chemical vapor transportation method, a vapor growth method, a sputtering method and a laser abrasion method.

12. A method of producing a phosphor film according to claim 7, wherein the additive element comprises at least one element selected from the group consisting of Ag, Cu and Au.
